(19) United States
(12) Patent Application Publication
(10) Pub. No.: US 2012/0080224 A1
(43) Pub. Date: Apr. 5, 2012

(54) Circuit board for signal transmission and method of manufacturing the same

(75) Inventors: Je Gwang Yoo, Yongin-si (KR); Bong Kyu Choi, Cheongju-si (KR); Yong Soo An, Busan (KR)

(73) Assignee: Samsung Electro-Mechanics Co., Ltd., Suwon (KR)

(21) Appl. No.: 13/137,871

(22) Filed: Sep. 20, 2011

(30) Foreign Application Priority Data
Oct. 5, 2010 (KR) 10-2010-0096604

(51) Int. Cl. H05K 9/00; H05K 3/02; H05K 3/46

(52) U.S. Cl. 174/350; 29/846; 29/847

(57) ABSTRACT

Provided is a circuit board for signal transmission and a method of manufacturing the same. The circuit board for signal transmission includes a first insulating layer, a plurality of signal interconnection disposed on the first insulating layer, ground interconnections disposed on the first insulating layer at both sides of the plurality of signal interconnections, a second insulating layer disposed on the first insulating layer including the plurality of signal interconnections and ground interconnections, a first shield layer disposed on the second insulating layer, a first shield wall for electrically connecting the ground interconnections and the first shield layer and passing through the second insulating layer, a second shield layer disposed under the first insulating layer, and a second shield wall for electrically connecting the ground interconnections and the second shield layer and passing through the first insulating layer.

This application claims the benefit under 35 U.S.C. Section 119 of Korean Patent Application Serial No. 10-2010-0096604, entitled CIRCUIT BOARD FOR SIGNAL TRANSMISSION AND METHOD OF MANUFACTURING THE SAME filed on Oct. 5, 2010, which is hereby incorporated by reference in its entirety into this application.

### BACKGROUND OF THE INVENTION

1. Field of the Invention

The present invention relates to a circuit board for signal transmission and a method of manufacturing the same, and more particularly, to a circuit board for signal transmission capable of reducing noises, and a method of manufacturing the same.

2. Description of the Related Art

In recent times, as displays evolve as high resolution displays such as Full HDTV and 3D TV, a large capacity of signal transmission between a display drive circuit and a T-Con board is needed. Accordingly, an image transmission cable is converted from a parallel interface of a low-voltage differential signaling type into a serial interface. The serial interface can reduce the number of signal lines and increase transmission per signal line.

However, since the serial interface has a high transmission speed of each channel, if a shield is insufficient, noises affected by external environments may be increased.

### SUMMARY OF THE INVENTION

The present invention has been invented in order to overcome the above-described problems and it is, therefore, an object of the present invention to provide a circuit board for signal transmission including a shield member surrounding a plurality of signal interconnections to reduce noises, and a method of manufacturing the same.

In accordance with one aspect of the present invention to achieve the object, there is provided a circuit board for signal transmission including: a first insulating layer; a plurality of signal interconnection disposed on the first insulating layer; ground interconnections disposed on the first insulating layer at both sides of the plurality of signal interconnections; a second insulating layer disposed on the first insulating layer including the plurality of signal interconnections and ground interconnections; a first shield layer disposed on the second insulating layer; a first shield wall for electrically connecting the ground interconnections and the first shield layer and passing through the second insulating layer; a second shield layer disposed under the first insulating layer; and a second shield wall for electrically connecting the ground interconnections and the second shield layer and passing through the first insulating layer.

Here, the circuit board for signal transmission may further include first and second added shield layers disposed on the first and second shield layers, respectively.

In addition, the circuit board for signal transmission may further include first and second coverlay layers for covering outer surfaces of the first shield layer and the first shield wall and outer surfaces of the second shield layer and the second shield wall.

Further, the circuit board for signal transmission may further include a first adhesion layer disposed between the second insulating layer and the first shield layer.

Furthermore, the circuit board for signal transmission may further include a second adhesion layer disposed between the first insulating layer and the second shield layer.

In addition, the circuit board for signal transmission may further include a third insulating layer disposed between the first insulating layer and the second shield layer.

In accordance with another aspect of the present invention to achieve the object, there is provided a method of manufacturing a circuit board for signal transmission including: forming a plurality of signal interconnections and ground interconnections disposed at both sides of the plurality of signal interconnections on a first insulating layer; forming a first shield wall passing through a second insulating layer, a first shield layer and a second insulating layer on the first insulating layer including the plurality of signal interconnections and ground interconnections; and forming a second shield wall passing through a second shield layer and the first insulating layer on the first insulating layer.

Here, forming the first shield wall passing through the second insulating layer, the first shield layer and the second insulating layer on the first insulating layer including the plurality of signal interconnections and ground interconnections may include: forming a second insulating layer having a first opening for exposing the ground interconnections on the first insulating layer including the plurality of signal interconnections and ground interconnections; forming a first adhesion layer on the second insulating layer; forming a first metal layer on the first adhesion layer; etching the first metal layer to form a first shield layer, and passing through the first adhesion layer to expose the ground interconnections; and forming a first shield wall connected to the ground interconnections and filled into the first opening.

In addition, forming the first shield wall passing through the second insulating layer, the first shield layer and the second insulating layer on the first insulating layer including the plurality of signal interconnections and ground interconnections may include: forming a second insulating layer having a first opening for exposing the ground interconnections on the first insulating layer including the plurality of signal interconnections and ground interconnections; forming a first adhesion layer for exposing the ground interconnections on the second insulating layer and a first release layer in the first opening; forming a first metal layer on the first adhesion layer; etching the first metal layer to form a first shield layer; removing the release layer to expose the ground interconnections; and forming a first shield wall connected to the ground interconnections and filled into the first opening.

Further, forming the first shield wall passing through the second insulating layer, the first shield layer and the second insulating layer on the first insulating layer including the plurality of signal interconnections and ground interconnections may include: laminating a second insulating layer including a metal layer on the first insulating layer including the plurality of signal interconnections and ground interconnections; forming an opening for exposing the ground interconnections on the metal layer and the second insulating layer, and forming a first shield layer; and forming a first shield wall connected to the ground interconnections and filled into the opening.

Furthermore, forming the second shield wall passing through the second shield layer and the first insulating layer under the first insulating layer may include: forming a second opening for exposing the ground interconnections in the first insulating layer; forming a second adhesion layer under the first insulating layer; forming a second metal layer on the second adhesion layer; etching the second metal layer to form a second shield layer and passing through the second adhesion layer to expose the ground interconnections; and forming a second shield wall connected to the ground interconnections and filled into the second opening.

In addition, forming the second shield wall passing through the second shield layer and the first insulating layer under the first insulating layer may include: forming a second opening for exposing the ground interconnections in the first insulating layer; forming a second adhesion layer for exposing the ground interconnections under the second insulating layer and a second release layer in the second opening; forming a second metal layer on the second adhesion layer; etching the second metal layer to form a second shield layer; removing the release layer to expose the ground interconnections; and forming a second shield wall connected to the ground interconnection and filled into the second opening.

Further, forming the second shield wall passing through the second shield layer and the first insulating layer under the first insulating layer may include: forming a second opening for exposing the ground interconnections in the first insulating layer; laminating a third insulating layer including a metal layer under the second insulating layer; forming a third opening for exposing the ground interconnections and forming a second shield layer on the metal layer or a third insulating layer; and forming a second shield wall connected to the ground interconnection and filled into the second opening and the third opening.

Furthermore, the method of manufacturing a circuit board for signal transmission may further include forming first and second added shield layers on the first and second shield layers, respectively.

In addition, the method of manufacturing a circuit board for signal transmission may further include, after forming the second shield wall connected to the ground interconnections and filled into the second opening, etching edges of the first and second shield layers to expose side surfaces of the first and second shield walls; and forming a coverlay layer for covering upper parts of the exposed first and second shield layers and side surfaces of the first and second shield walls.

### BRIEF DESCRIPTION OF THE DRAWINGS

These and/or other aspects and advantages of the present general inventive concept will become apparent and more readily appreciated from the following description of the embodiments, taken in conjunction with the accompanying drawings of which:

FIG. 1 is a cross-sectional view of a circuit board for signal transmission in accordance with a first exemplary embodiment of the present invention;

FIG. 2 is a cross-sectional view of a circuit board for signal transmission in accordance with a second exemplary embodiment of the present invention;

FIGS. 3 to 12 are cross-sectional views for explaining a method of manufacturing a circuit board for signal transmission in accordance with a third exemplary embodiment of the present invention;

FIGS. 13 to 15 are cross-sectional views for explaining a method of manufacturing a circuit board for signal transmission in accordance with a fourth exemplary embodiment of the present invention; and

FIGS. 16 to 20 are cross-sectional views for explaining a method of manufacturing a circuit board for signal transmission in accordance with a fifth exemplary embodiment of the present invention.

### DETAILED DESCRIPTION OF THE PREFERABLE EMBODIMENTS

Hereinafter, a circuit board for signal transmission of the present invention will be described in detail with reference to the accompanying drawings. The following embodiments are provided as examples to fully convey the spirit of the invention to those skilled in the art.

Therefore, the present invention should not be construed as limited to the embodiments set forth herein and may be embodied in different forms. And, the size and the thickness of an apparatus may be overdrawn in the drawings for the convenience of explanation. The same components are represented by the same reference numerals hereinafter.

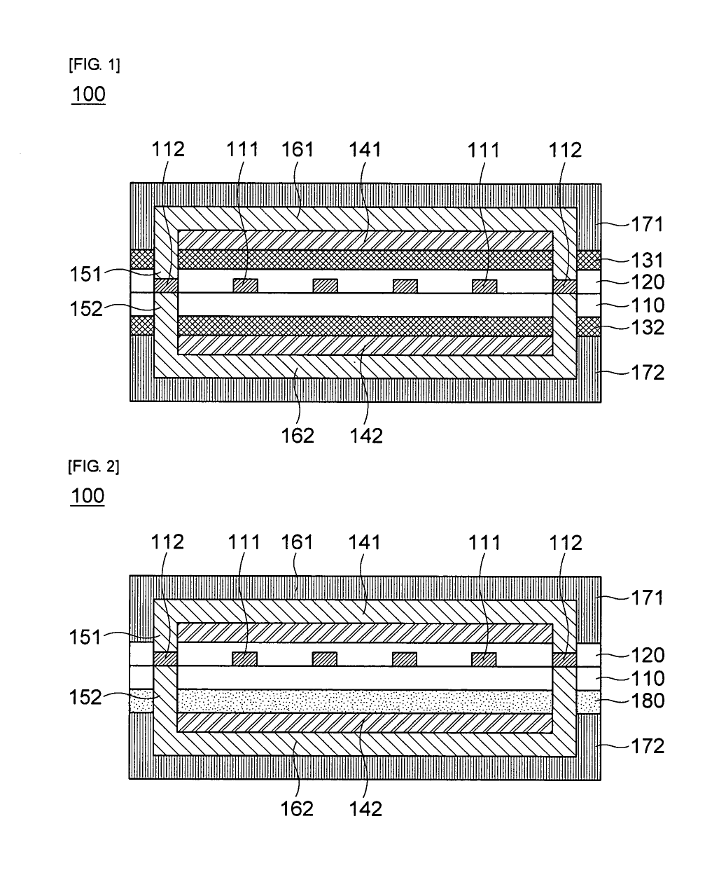

FIG. 1 is a cross-sectional view of a circuit board for signal transmission in accordance with a first exemplary embodiment of the present invention.

Referring to FIG. 1, a circuit board 100 for signal transmission in accordance with a first exemplary embodiment of the present invention may include a first insulating layer 110, signal interconnections 111, ground interconnections 112, a second insulating layer 120, first and second shield layers 141 and 142, and first and second shield walls 151 and 152.

Specifically, the plurality of signal interconnections 111 and ground interconnections 112 are disposed on the first insulating layer 110.

The first insulating layer 110 may be formed of a resin, for example, epoxy-based resin. In addition, the resin may be impregnated into a glass fiber.

The plurality of signal interconnections 111 may be disposed to be spaced apart from each other. The ground interconnections 112 may be disposed at both sides of the plurality of signal interconnections 111. The plurality of signal interconnections 111 and ground interconnections 112 may be formed of the same conductive material. Here, the conductive material may include one or two or more selected from copper, nickel, gold and aluminum.

The second insulating layer 120 may be disposed on the first insulating layer 110 including the plurality of signal interconnections 111 and ground interconnections 112. Here, the second insulating layer 120 may include an opening through which the ground interconnection 112 is exposed.

The second insulating layer 120 may be formed of a single material or a mixed material selected from epoxy-based resin, silicon-based resin, polyimide-based resin, and phenol-based resin.

The first shield layer 141 may be disposed on the second insulating layer 120. Here, the first shield layer 141 may be disposed to cover the plurality of signal interconnections 111 to block noises or electromagnetic waves from the exterior to the plurality of signal interconnections 111 or from the plurality of signal interconnections 111 to the exterior.

The first shield wall 151 may be filled into the opening of the second insulating layer 120. Accordingly, one end of the first shield wall 151 may be electrically connected to the ground interconnection 112 exposed by the opening of the second insulating layer 120. The first shield wall 151 may be disposed to pass through the second insulating layer 120. That is, the first shield wall 151 may be disposed at side surfaces of the plurality of signal interconnections.

In addition, the other end of the first shield wall 151 may be electrically connected to the first shield wall 141. Accordingly, the first shield wall 151 may electrically connect the first shield layer 141 to the ground interconnections 112.

Therefore, the first shield layer 141 and the first shield wall 151 may be configured to surround an upper part and side surfaces of the plurality of signal interconnections 111 to prevent emission of electromagnetic waves from the upper part and side surfaces of the plurality of signal interconnections 111. In addition, it is also possible to prevent interference with the noises intruded into the upper surface and side surfaces of the plurality of signal interconnections 111.

In addition, a first added shield layer 161 electrically connected to the first shield wall 151 may be disposed on the first shield layer 141. The first added shield layer 161 may be integrally formed with the first shield wall 151. Here, since the first added shield layer 161 is provided, the thickness of the shield layer of the upper part may be increased to more effectively block electromagnetic waves and noises. As the first added shield layer 161 is further provided, the thickness of the upper part may be increased to enhance mechanical durability of the circuit board for signal transmission.

Further, a first adhesion layer 131 may be further interposed between the first insulating layer 110 and the first shield layer 141. The first adhesion layer 131 may function to attach the first shield layer 141 to the first insulating layer 110.

The first adhesion layer 131 may include one or two or more selected from epoxy-based resin, polyimide-based resin, silicon-based resin, and phenol-based resin, and the embodiment of the present invention is not limited to the material of the first adhesion layer 131.

Meanwhile, a second shield layer 142 and a second shield wall 152 may be further disposed under the first insulating layer 110. The second shield wall 152 may pass through the first insulating layer 110 to be electrically connected to the ground interconnections 112. At this time, the second shield wall 152 may be connected to the second shield layer 142 so that the second shield layer 142 can be electrically connected to the ground interconnections 112.

Therefore, the second shield layer 142 and the second shield wall 152 may be configured to surround a lower part and side surfaces of the plurality of signal interconnections 111 to prevent emission of electromagnetic waves from the lower part and side surfaces of the plurality of signal interconnections 111. In addition, it is possible to prevent interference with noises intruded into the lower surface and side surfaces of the plurality of signal interconnection 111.

That is, since the plurality of signal interconnections 111 are surrounded by the shield members, i.e., the first and second shield layers 141 and 142 and the first and second shield walls 151 and 152, the plurality of signal interconnections 111 may be blocked from the external noises and can prevent emission of the electromagnetic waves and noised to the exterior.

In addition, a second added shield layer 162 electrically connected to the first shield wall 151 may be disposed on an upper part, i.e., an outside, of the second shield layer 142. The second added shield layer 162 may be integrally formed with the second shield wall 152. Here, as the second added shield layer 162 is provided, the thickness of the shield layer of the upper part may be increased to more effectively block electromagnetic waves and noises. In addition, as the second added shield layer 162 is further provided, the thickness of the upper part may be increased to enhance mechanical durability of the circuit board for signal transmission.

Further, a second adhesion layer 132 may be further interposed between the second insulating layer 120 and the second shield layer 142. The second adhesion layer 132 may function to attach the second shield layer 142 to the second insulating layer 120.

The second adhesion layer 132 may include one or mixed resin of two or more selected from epoxy-based resin, polyimide-based resin, silicon-based resin, and phenol-based resin, and the embodiment of the present invention is not limited to the material of the second adhesion layer 132.

In addition, the first and second shield layers 141 and 142 and the first and second shield walls 151 and 152 may be exposed to the exterior. At this time, in order to protect the first and second shield layers 141 and 142 and the first and second shield walls 151 and 152 from the exterior, outer surfaces of the first shield layer 141 and the first shield wall 151 and outer surfaces of the second shield layer 142 and the second shield wall 152 may be covered by first and second coverlay layers 171 and 172, respectively. Here, the first and second coverlay layers 171 and 172 may include one or a mixed resin of two or more selected from epoxy-based resin, polyimide-based resin, acryl-based resin and silicon-based resin.

Therefore, as described in the first embodiment of the present invention, since the shield members are provided to surround the plurality of signal interconnections, the noises and electromagnetic waves from the exterior can be blocked and interference with the external signal line can also be securely blocked.

FIG. 2 is a cross-sectional view of a circuit board for signal transmission in accordance with a second exemplary embodiment of the present invention. Here, except that the insulating layer is further provided instead of the adhesion layer, the circuit board for signal transmission in accordance with a second exemplary embodiment of the present invention may have the same constitution as the circuit board for signal transmission in accordance with a first exemplary embodiment of the present invention. Accordingly, the same description of the second embodiment as the first embodiment will not be repeated, and like elements are designated by like reference numerals.

Referring to FIG. 2, the circuit board for signal transmission in accordance with a second exemplary embodiment of the present invention may include a first insulating layer 110, a plurality of signal interconnection 111 disposed on the first insulating layer 110, ground interconnections 112 disposed on the first insulating layer 110 at both sides of the plurality of signal interconnections 111, a second insulating layer 120 disposed on the first insulating layer 110 including the plurality of signal interconnections 111 and ground interconnections 112, a first shield layer 141 disposed on the second insulating layer 120, a first shield wall 151 for electrically connecting the ground interconnections 112 and the first shield layer 141 and passing through the second insulating layer 120, a second shield layer 142 disposed under the first insulating layer 110, and a second shield wall 152 for electrically connecting the ground interconnections 112 and the second shield layer 142 and passing through the first insulating layer 110.

A third insulating layer 180 may be further disposed between the first insulating layer 110 and the second shield layer 142. Here, the second shield layer 142 may be adhered on the first insulating layer 110 through the third insulating layer 180.

The second and third insulating layers 120 and 180 may be formed of a resin coated copper (RCC). That is, the first and second shield layers 141 and 142 may be adhered by adhesion of the second and third insulating layers 120 and 180 themselves, respectively.

Therefore, the first and second shield layers are formed using the resin coated copper (RCC) in accordance with a second exemplary embodiment of the present invention to attach the first and second shield layers to the first insulating layer, without a separate adhesion layer, reducing process cost and further reducing the thickness thereof.

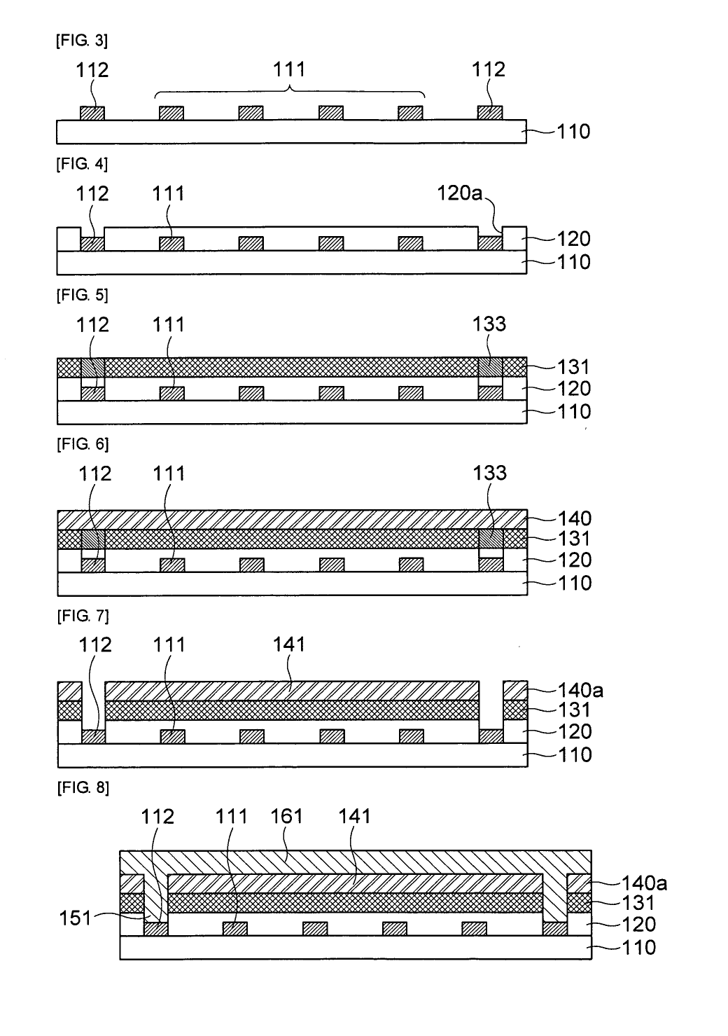

FIGS. 3 to 12 are cross-sectional views for explaining a method of manufacturing a circuit board for signal transmission in accordance with a third exemplary embodiment of the present invention.

Referring to FIG. 3, in order to manufacture a circuit board for signal transmission in accordance with a third exemplary embodiment of the present invention, first, a plurality of signal interconnections 111 and ground interconnections 112 are formed on a first insulating layer 110.

In order to form the plurality of signal interconnections 111 and ground interconnections 112, a resin coated copper (RCC) is provided. Here, the RCC may include a first insulating layer 110 and a copper layer disposed on the first insulating layer 110. Here, the first insulating layer 110 may be formed of a resin, for example, epoxy-based resin. In addition, the resin may be impregnated into a glass fiber.

After laminating a dry film on the copper layer, an exposure and development process is performed on the dry film to form a dry pattern. The copper layer may be etched using the dry pattern as an etching mask to form a plurality of signal interconnections 111 spaced apart from each other and ground interconnections 112 disposed at both sides of the plurality of signal interconnections 111. Next, the dry pattern is delaminated from the first insulating layer 110 including the plurality of signal interconnections 111 and ground interconnections 112. While it has been described that the plurality of signal interconnections 111 and ground interconnections 112 are formed of copper, the material is not limited thereto but may be one metal or alloy of two or more selected from nickel, gold and aluminum.

Referring to FIG. 4, after forming the plurality of signal interconnections 111 and ground interconnections 112, a second insulating layer 120 is formed on the first insulating layer 110 including the plurality of signal interconnections 111 and ground interconnections 112. Here, the second insulating layer 120 has first openings 120a through which the ground interconnections 112 are exposed.

The second may be formed through a printing process using a liquefied composition including an insulating resin. Here, the insulating resin may include a single material or a mixed material of two or more selected from epoxy-based resin, silicon-based resin, polyimide-based resin, and phenol-based resin.

Referring to FIG. 5, after forming the second insulating layer 120, a release layer 133 is formed in the second opening, and a first adhesion layer 131 is formed on the second insulating layer 120.

Here, the release layer 133 and the first adhesion layer 131 may be formed through the printing process.

Here, the first adhesion layer 131 may be formed of, for example, epoxy-based resin. In addition, the release layer 133 may be easily separated from the copper layer that forms the ground interconnections 112, and may be formed of a material that can be easily delaminated by a stripping solution such as NaOH solution, which is widely used in a general substrate process, for example, polyvinyl-based resin.

Referring to FIG. 6, after forming the release layer 133 and the first adhesion layer 131, a metal layer 140 is laminated on the release layer 133 and the first adhesion layer 131. Here, the first metal layer 140 may be formed of copper.

Referring to FIG. 7, after laminating the first metal layer 140, the first metal layer 140 is etched to form a first shield layer 141. The first shield layer 141 may be disposed on the first adhesion layer 131 corresponding to the plurality of signal interconnections 111. At this time, the first metal layer 140 may be formed on an edge region of the first shield layer 141. Here, the etching of the first metal layer 140 may be selectively performed using the dry pattern.

Next, the release layer 133 is removed to expose the ground interconnections 112. Accordingly, during a process of forming the first adhesion layer 131, the release layer 133 may function to prevent contamination of the ground interconnections 112.

Referring to FIG. 8, a first shield wall 151 is formed to be connected to the ground interconnections 112 and filled into the first opening 120a through a plating process.

In addition, a first added shield layer 141 electrically connected to the first shield wall 151 may be further formed on the first shield layer 141. In the plating process, an extension part of the first added shield layer 141 may be further formed on a first dummy metal layer 140a.

Therefore, the shield members, i.e., the first shield wall 151, the first shield layer 141 and the first added shield layer 141 may be formed on side surfaces and upper parts of the signal interconnections 111 and ground interconnections 112.

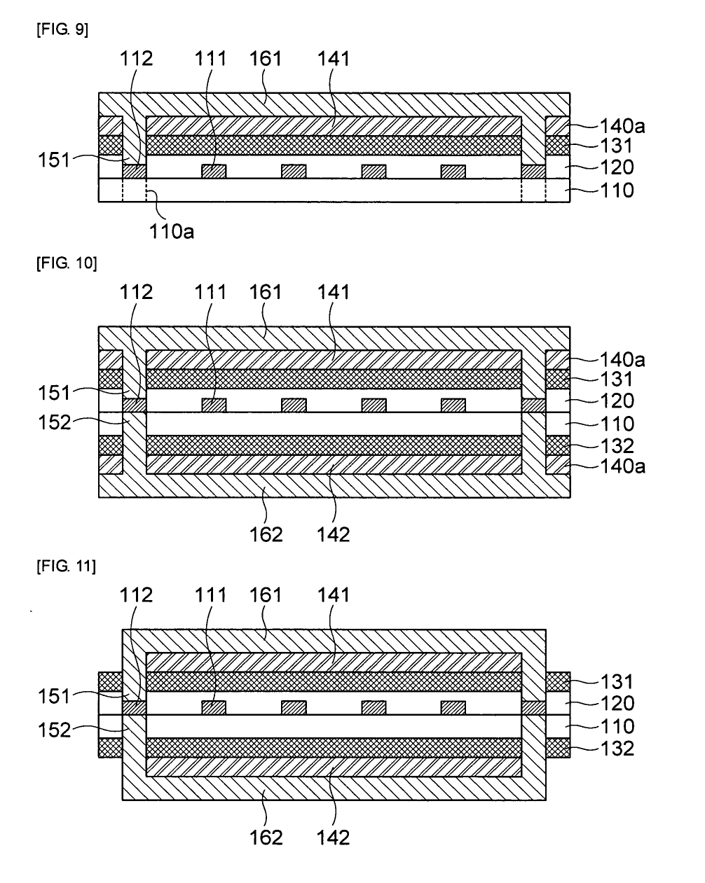

Referring to FIG. 9, a second opening is formed in the first insulating layer 110 to expose lower surfaces of the ground interconnections 112. Here, the second opening may be formed through a mechanical drilling method or a laser drilling method.

Referring to FIG. 10, a second shield wall 152 connected to the second shield layer 142 and the second shield layer 142 and passing through the second insulating layer 120 is formed under the first insulating layer 110. Here, during a process of forming the second shield wall 152, a second added shield layer 162 may be further formed on the second shield layer 142.

The second shield layer 142 and the second shield wall 152 may be formed using a process of forming the first shield layer 141 and the first shield wall 151.

Specifically, a second adhesion layer 132 for exposing the ground interconnections 112 is formed under the first insulating layer 110 and the release layer 133 is formed on the exposed ground interconnections 112 in the second opening.

Next, after laminating the second metal layer on the second adhesion layer 132, the second metal layer is etched to form the second shield layer 142. At this time, the second dummy metal layer 140b may be formed on an edge of the second shield layer 142.

Next, after removing the release layer 133 to expose the ground interconnections 112, the second shield wall 152 filled in the second opening is formed through the plating process. In the plating process, the second added shield layer 162 may be further formed on the second shield layer 142. In addition, the second added shield layer may further extend on the second dummy metal layer 140b.

Referring to FIG. 11, the extension parts of the first and second dummy metal layers 140a and 140b and the first and second added shield layers 161 and 162 are removed. Here, a process of removing the extension parts of the first and second dummy metal layers 140a and 140b and the first and second added shield layers 161 and 162 may be performed through an etching process, after forming the shield members, i.e., the first and second shield layers 141 and 142 using the dry film. At this time, side surfaces of the first and second shield walls 151 and 152 may be exposed to the exterior.

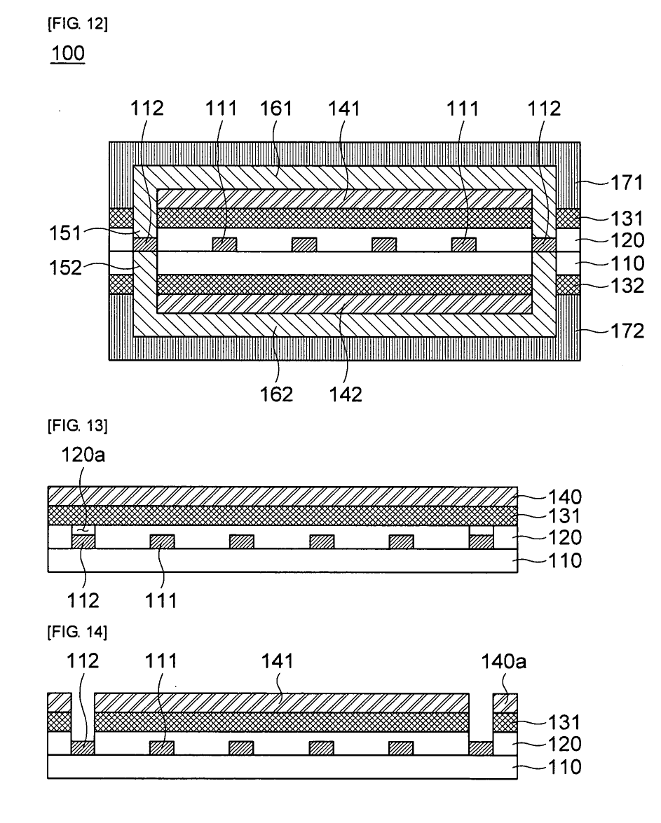

Referring to FIG. 12, a first coverlay layer 171 for covering an upper surface of the first shield layer 141 and side surfaces of the first shield wall 151 exposed to the exterior and a second coverlay layer 172 for covering an upper surface of the second shield layer 142 and side surfaces of the second shield wall 152 exposed to the exterior may be formed. Here, when the first and second added shield layers 161 and 162 are formed, the first and second coverlay layers 171 and 172 may be formed to cover the upper surfaces of the first and second added shield layers 161 and 162, respectively.

The first and second coverlay layers 171 and 172 may include one or a mixed resin of two or more selected from epoxy-based resin, polyimide-based resin, acryl-based resin and silicon-based resin.

The first and second coverlay layers 171 and 172 may be formed by applying resin or attaching a separate resin film.

While it has been described that one product is formed in the embodiment of the present invention, the embodiment is not limited thereto but may form a plurality of products through one process using a mother substrate.

Here, when the plurality of products are formed, after forming the first and second coverlay layers 171 and 172, a routing process may be further performed to separate the products.

Therefore, as described in the embodiment of the present invention, the plurality of signal interconnections and shield members may be formed through a process of forming a printed circuit board, i.e., the plating process and the etching process. Accordingly, the circuit board for signal transmission capable of preventing emission of noises and electromagnetic waves can use manufacturing equipment of a printed circuit board to reduce equipment investment cost. In addition, since mass production is possible, manufacturing cost of the circuit board for signal transmission can be reduced.

FIGS. 13 to 15 are cross-sectional views for explaining a method of manufacturing a circuit board for signal transmission in accordance with a fourth exemplary embodiment of the present invention.

Here, a process of manufacturing a circuit board for signal transmission in accordance with a fourth exemplary embodiment of the present invention is the same as the process of manufacturing a circuit board for signal transmission of the third embodiment, except that the release layer is not formed, and detailed description thereof will not be repeated.

Referring to FIG. 13, in order to manufacture the circuit board for signal transmission in accordance with a fourth exemplary embodiment of the present invention, a plurality of signal interconnections 111 and ground interconnections 112 disposed at both sides of the plurality of signal interconnections 111 are formed on a first insulating layer 110.

Next, a second insulating layer 120, a first adhesion layer 131 and a first metal layer 140 are sequentially formed on the first insulating layer 110 including the plurality of signal interconnections 111 and ground interconnections 112. Here, the second insulating layer 120 may include first openings 120a through which the ground interconnections 112 are exposed.

Referring to FIG. 14, an opening passing through a first metal layer 140 and a first adhesion layer 131 to expose the ground interconnections 112 are formed by a laser drill.

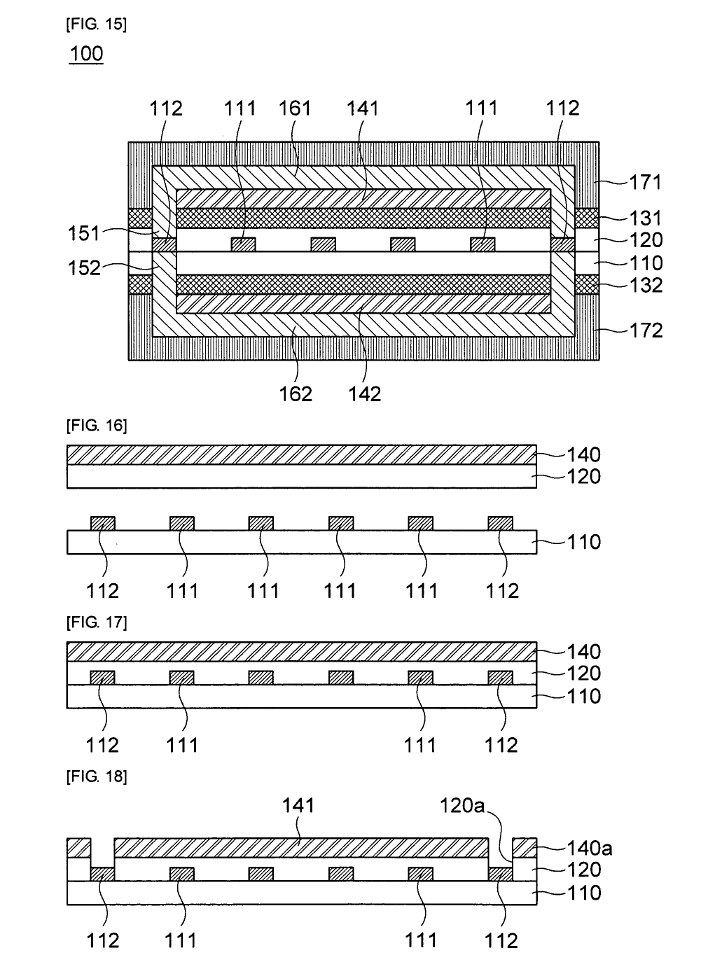

Referring to FIG. 15, a first shield wall 151 passing through the first shield layer 141 and the second insulating layer 120 is formed on the second insulating layer 120.

Next, after sequentially forming a second adhesion layer 132 and a second metal layer under the first insulating layer 110, the second metal layer is etched to form a second shield layer 142.

Next, a second shield wall 152 connected to the second shield layer 142 and passing through the first insulating layer 110 is formed.

In addition, during a process of forming the first and second shield walls 151 and 152, first and second added shield layers 161 and 162 disposed on the first and second shield layers 141 and 142 may be further formed.

Next, first and second dummy metal layers 140a and 140b formed during the process of forming the first and second shield layers 141 and 142 and extension parts of first and second added shield layers 161 and 162 generated during the process of forming the first and second shield layers 161 and 162 are removed.

Next, first and second coverlay layers 171 and 172 for covering the first and second shield layers 141 and 142 and the first and second shield layers 151 and 152 exposed to the exterior may be formed.

As described in the embodiment of the present invention, the adhesion layer and the metal layer are configured to integrally pass therethrough by a laser drill, making it possible to simplify a manufacturing process.

FIGS. 16 to 20 are cross-sectional views for explaining a method of manufacturing a circuit board for signal transmission in accordance with a fifth exemplary embodiment of the present invention.

Here, a process of manufacturing a circuit board for signal transmission in accordance with a fifth exemplary embodiment of the present invention may include the same manufacturing process as the fourth embodiment, except that the adhesion layer is not formed, and detailed description thereof will not be repeated.

Referring to FIG. 16, in order to manufacture a circuit board for signal transmission in accordance with a fifth exemplary embodiment of the present invention, first, a plurality of signal interconnection 111 and ground interconnections 112 disposed at both sides of the plurality of signal interconnections 111 are formed on a first insulating layer 110.

A second insulating layer 120 including a metal layer is provided on the first insulating layer 110 including the plurality of signal interconnections 111 and ground interconnections 112. Here, the second insulating layer 120 including the metal layer may be formed of a resin coated copper (RCC).

Referring to FIG. 17, the second insulating layer 120 including a first metal layer 140 is laminated on the first insulating layer 110 including the plurality of signal interconnections 111 and ground interconnections 112.

Referring to FIG. 18, a first opening 120a and a first shield layer 141 passing through the first metal layer 140 and the second insulating layer 120 and exposing the ground interconnections 112 may be formed using a laser drill.

Referring to FIG. 19, a plating process may be performed to form a first shield wall 151 connected to the first shield layer 141 and filled into the first opening.

During a process of forming the first shield wall 151, a first added shield layer 161 may be further formed on the first shield layer 141.

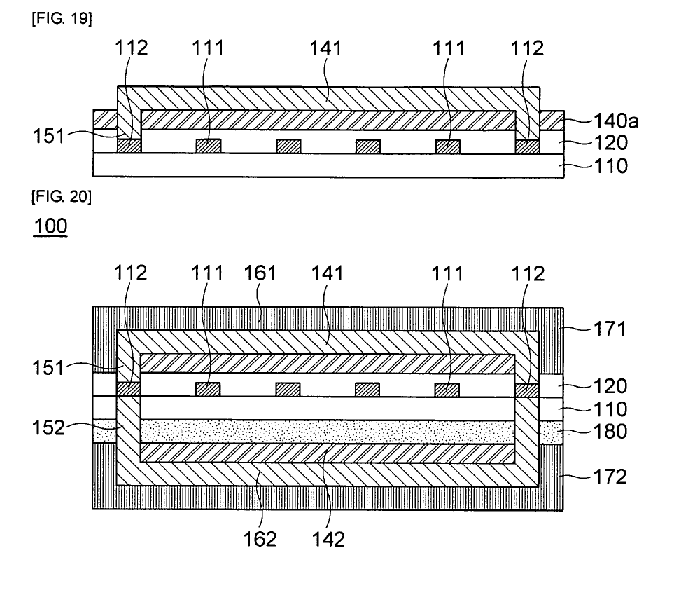

Referring to FIG. 20, a second shield layer 142 and a second shield wall 152 may be formed using a process of forming the first shield layer 141 and the first shield wall 152 under the first insulating layer 110.

Specifically, an opening for exposing lower parts of the ground interconnections 112 is formed in the first insulating layer 110. Next, a third insulating layer 180 including the first metal layer 140, i.e., a resin coated copper (RCC), may be laminated under the first insulating layer 110.

Next, after etching the metal layer to form the second shield layer 142, the plating process is performed to form the second shield wall 152. Here, during the plating process, a second added shield layer 162 may be further formed on the second shield layer 142.

Next, extension parts of first and second dummy metal layers 140a and 140b generated during a process of forming the first and second shield layers 141 and 142 and first and second added shield layers 161 and 162 generated during the first and second added shield layers 161 and 162 are removed.

Next, first and second coverlay layers 171 and 172 for covering the first and second shield layers 141 and 142 and the first and second shield walls 151 and 152 disposed to the exterior may be formed.

Therefore, as described in the embodiment of the present invention, since the insulating layer and the metal layer are formed through a lamination process using the RCC, without forming a separate adhesion layer, the number of processes can be reduced.

As can be seen from the foregoing, since the circuit board for signal transmission in accordance with an exemplary embodiment of the present invention includes the shield members including the plurality of signal interconnections, it is possible to block noises and electromagnetic waves from the exterior and thoroughly prevent interference with external signal lines.

Since the circuit board for signal transmission in accordance with an exemplary embodiment of the present invention can be manufactured using a manufacturing apparatus for a conventional printed circuit board, the circuit board can be economically manufactured without additional equipment investment.

In addition, since the circuit board for signal transmission in accordance with an exemplary embodiment of the present invention can be manufactured through a process of forming a plurality of products through a single process and cutting each product, mass production is possible.

As described above, although the preferable embodiments of the present invention have been shown and described, it will be appreciated by those skilled in the art that substitutions, modifications and variations may be made in these embodiments without departing from the principles and spirit of the general inventive concept, the scope of which is defined in the appended claims and their equivalents.

What is claimed is:

1. A circuit board for signal transmission comprising:
a first insulating layer;
a plurality of signal interconnection disposed on the first insulating layer;
ground interconnections disposed on the first insulating layer at both sides of the plurality of signal interconnections;
a second insulating layer disposed on the first insulating layer including the plurality of signal interconnections and ground interconnections;
a first shield layer disposed on the second insulating layer;
a first shield wall for electrically connecting the ground interconnections and the first shield layer and passing through the second insulating layer;
a second shield layer disposed under the first insulating layer; and
a second shield wall for electrically connecting the ground interconnections and the second shield layer and passing through the first insulating layer.

2. The circuit board for signal transmission according to claim 1, further comprising first and second added shield layers disposed on the first and second shield layers, respectively.

3. The circuit board for signal transmission according to claim 1, further comprising first and second coverlay layers for covering outer surfaces of the first shield layer and the first shield wall and outer surfaces of the second shield layer and the second shield wall.

4. The circuit board for signal transmission according to claim 1, further comprising a first adhesion layer disposed between the second insulating layer and the first shield layer.

5. The circuit board for signal transmission according to claim 4, further comprising a second adhesion layer disposed between the first insulating layer and the second shield layer.

6. The circuit board for signal transmission according to claim 4, further comprising a third insulating layer disposed between the first insulating layer and the second shield layer.

7. A method of manufacturing a circuit board for signal transmission comprising:
forming a plurality of signal interconnections and ground interconnections disposed at both sides of the plurality of signal interconnections on a first insulating layer;
forming a first shield wall passing through a second insulating layer, a first shield layer and a second insulating layer on the first insulating layer including the plurality of signal interconnections and ground interconnections; and
forming a second shield wall passing through a second shield layer and the first insulating layer on the first insulating layer.

8. The method of manufacturing a circuit board for signal transmission according to claim 7, wherein the forming the first shield wall passing through the second insulating layer, the first shield layer and the second insulating layer on the first insulating layer including the plurality of signal interconnections and ground interconnections comprises:
forming a second insulating layer having a first opening for exposing the ground interconnections on the first insulating layer including the plurality of signal interconnections and ground interconnections;
forming a first adhesion layer on the second insulating layer;
forming a first metal layer on the first adhesion layer;
etching the first metal layer to form a first shield layer, and passing through the first adhesion layer to expose the ground interconnections; and
forming a first shield wall connected to the ground interconnections and filled into the first opening.

9. The method of manufacturing a circuit board for signal transmission according to claim 7, wherein the forming the first shield wall passing through the second insulating layer, the first shield layer and the second insulating layer on the first insulating layer including the plurality of signal interconnections and ground interconnections comprises:
forming a second insulating layer having a first opening for exposing the ground interconnections on the first insulating layer including the plurality of signal interconnections and ground interconnections;
forming a first adhesion layer for exposing the ground interconnections on the second insulating layer and a first release layer in the first opening;
forming a first metal layer on the first adhesion layer;
etching the first metal layer to form a first shield layer;
removing the release layer to expose the ground interconnections; and
forming a first shield wall connected to the ground interconnections and filled into the first opening.

10. The method of manufacturing a circuit board for signal transmission according to claim 7, wherein the forming the first shield wall passing through the second insulating layer, the first shield layer and the second insulating layer on the first insulating layer including the plurality of signal interconnections and ground interconnections comprises:
laminating a second insulating layer including a metal layer on the first insulating layer including the plurality of signal interconnections and ground interconnections;
forming an opening for exposing the ground interconnections on the metal layer and the second insulating layer, and forming a first shield layer; and
forming a first shield wall connected to the ground interconnections and filled into the opening.

11. The method of manufacturing a circuit board for signal transmission according to claim 7, wherein the forming the second shield wall passing through the second shield layer and the first insulating layer under the first insulating layer comprises:
forming a second opening for exposing the ground interconnections in the first insulating layer;
forming a second adhesion layer under the first insulating layer;
forming a second metal layer on the second adhesion layer;
etching the second metal layer to form a second shield layer and passing through the second adhesion layer to expose the ground interconnections; and
forming a second shield wall connected to the ground interconnections and filled into the second opening.

12. The method of manufacturing a circuit board for signal transmission according to claim 7, wherein the forming the second shield wall passing through the second shield layer and the first insulating layer under the first insulating layer comprises:
forming a second opening for exposing the ground interconnections in the first insulating layer;
forming a second adhesion layer for exposing the ground interconnections under the second insulating layer and a second release layer in the second opening;
forming a second metal layer on the second adhesion layer;
etching the second metal layer to form a second shield layer;
removing the release layer to expose the ground interconnections; and
forming a second shield wall connected to the ground interconnection and filled into the second opening.

13. The method of manufacturing a circuit board for signal transmission according to claim 7, wherein the forming the second shield wall passing through the second shield layer and the first insulating layer under the first insulating layer comprises:
forming a second opening for exposing the ground interconnections in the first insulating layer;
laminating a third insulating layer including a metal layer under the second insulating layer;
forming a third opening for exposing the ground interconnections and forming a second shield layer on the metal layer or a third insulating layer; and
forming a second shield wall connected to the ground interconnection and filled into the second opening and the third opening.

14. The method of manufacturing a circuit board for signal transmission according to claim 7, further comprising forming first and second added shield layers on the first and second shield layers, respectively.

15. The method of manufacturing a circuit board for signal transmission according to claim 7, further comprising, after forming the second shield wall connected to the ground interconnections and filled into the second opening,
etching edges of the first and second shield layers to expose side surfaces of the first and second shield walls; and
forming a coverlay layer for covering upper parts of the exposed first and second shield layers and side surfaces of the first and second shield walls.
